(19) United States
(12) Patent Application Publication
(10) Pub. No.: US 2026/0136692 A1
(43) Pub. Date: May 14, 2026

(54) IMAGING DEVICE AND ELECTRONIC APPARATUS

(71) Applicant: SONY SEMICONDUCTOR SOLUTIONS CORPORATION, KANAGAWA (JP)

(72) Inventor: HIROFUMI YAMADA, KANAGAWA (JP)

(21) Appl. No.: 18/706,298

(22) PCT Filed: Oct. 25, 2022
(86) PCT No.: PCT/JP2022/039648

§ 371 Date: Apr. 30, 2024

(30) Foreign Application Priority Data
Nov. 8, 2021 (JP) 2021-181928

(51) Int. Cl. H10F 39/00

(52) U.S. Cl. CPC H10F 39/8037

(57) ABSTRACT

The present disclosure relates to an imaging device and an electronic apparatus that can improve the influence on sensitivity differences between pixels.

An imaging device is provided, including a semiconductor substrate in which a plurality of pixels are formed, each pixel having a photoelectric conversion region, wherein diffusion regions are formed in the semiconductor substrate according to an incident angle at which light is incident on a pixel region in which the pixels are arranged two-dimensionally. The present disclosure can be applied to, for example, a CMOS type of imaging device.

### TECHNICAL FIELD

The present disclosure relates to an imaging device and an electronic apparatus, and particularly relates to an imaging device and an electronic apparatus that can improve the influence on sensitivity differences between pixels.

### BACKGROUND ART

There is known an imaging device having a pixel share structure in which a plurality of pixels share one floating diffusion and pixel transistors (see, for example, PTL 1).

### CITATION LIST

### Patent Literature

[PTL 1]

JP 2015-162646 A

### SUMMARY

### Technical Problem

In a structures such as a pixel share structure, an amount of color mixing from a certain pixel into another pixel may differ depending on the position of a diffusion region of pixel transistors. Such different amounts of color mixing may affect the sensitivity differences between pixels.

The present disclosure has been made in view of such circumstances, and is intended to improve the influence on sensitivity differences between pixels.

### Solution to Problem

An imaging device according to one aspect of the present disclosure includes a semiconductor substrate in which a plurality of pixels are formed, each pixel having a photoelectric conversion region, wherein diffusion regions are formed in the semiconductor substrate according to an incident angle at which light is incident on a pixel region in which the pixels are arranged two-dimensionally.

An electronic apparatus according to one aspect of the present disclosure includes an imaging device that includes a semiconductor substrate in which a plurality of pixels are formed, each pixel having a photoelectric conversion region, wherein diffusion regions are formed in the semiconductor substrate according to an incident angle at which light is incident on a pixel region in which the pixels are arranged two-dimensionally.

In the imaging device and the electronic apparatus according to one aspect of the present disclosure, a semiconductor substrate is provided in which a plurality of pixels are formed, each pixel having a photoelectric conversion region, wherein diffusion regions are formed in the semiconductor substrate according to an incident angle at which light is incident on a pixel region in which the pixels are arranged two-dimensionally.

The imaging device according to one aspect of the present disclosure may be an independent device or may be an internal block constituting a device.

### BRIEF DESCRIPTION OF DRAWINGS

FIG. 1

FIG. 1 is a diagram illustrating a configuration example of an imaging device to which the present disclosure is applied.

FIG. 2

FIG. 2 is a diagram illustrating a first example of a target area.

FIG. 3

FIG. 3 is a plan view illustrating an example of a planar layout of an upper right area.

FIG. 4

FIG. 4 is a cross-sectional view corresponding to the planar layout of FIG. 3.

FIG. 5

FIG. 5 is a diagram for explaining incident light in a plan view and a cross-sectional view.

FIG. 6

FIG. 6 is a plan view illustrating examples of a pixel array pattern in an upper right area.

FIG. 7

FIG. 7 is a diagram illustrating a second example of a target area.

FIG. 8

FIG. 8 is a plan view illustrating an example of a planar layout of an upper left area.

FIG. 9

FIG. 9 is a cross-sectional view corresponding to the planar layout of FIG. 8.

FIG. 10

FIG. 10 is a plan view illustrating examples of a pixel array pattern in an upper left area.

FIG. 11

FIG. 11 is a diagram illustrating a third example of a target area.

FIG. 12

FIG. 12 is a plan view illustrating an example of a planar layout of a lower left area.

FIG. 13

FIG. 13 is a cross-sectional view corresponding to the planar layout of FIG. 12.

FIG. 14

FIG. 14 is a plan view illustrating examples of a pixel array pattern in a lower left area.

FIG. 15

FIG. 15 is a diagram illustrating a fourth example of a target area.

FIG. 16

FIG. 16 is a plan view illustrating an example of a planar layout of a lower right area.

FIG. 17

FIG. 17 is a cross-sectional view corresponding to the planar layout of FIG. 16.

FIG. 18

FIG. 18 is a plan view illustrating examples of a pixel array pattern in a lower right area.

FIG. 19

FIG. 19 is a diagram illustrating an example of a target area in the case of an incident angle of 45°.

FIG. 20

FIG. 20 is a plan view illustrating an example of a planar layout of an upper right area in the case of an incident angle of 45°.

FIG. 21

FIG. 21 is a diagram illustrating an example of a target area in the case of an incident angle of 30°.

FIG. 22

FIG. 22 is a plan view illustrating an example of a planar layout of an upper right area in the case of an incident angle of 30°.

FIG. 23

FIG. 23 is a diagram illustrating an example of a target area in the case of an incident angle of 15°.

FIG. 24

FIG. 24 is a plan view illustrating an example of a planar layout of an upper right area in the case of an incident angle of 15°.

FIG. 25

FIG. 25 is a plan view illustrating a first example of a planar layout of a target area in the case of light incident in the horizontal or vertical directions.

FIG. 26

FIG. 26 is a plan view illustrating a second example of a planar layout of a target area in the case of light incident in the horizontal or vertical directions.

FIG. 27

FIG. 27 is a block diagram illustrating a configuration example of an electronic apparatus including the imaging device to which the present disclosure is applied.

FIG. 28

FIG. 28 is a block diagram illustrating an example of a schematic configuration of a vehicle control system.

FIG. 29

FIG. 29 is an explanatory diagram illustrating an example of installation positions of vehicle exterior information detection units and imaging units.

FIG. 30

FIG. 30 is a diagram illustrating an example of a schematic configuration of an endoscopic surgery system.

FIG. 31

FIG. 31 is a block diagram illustrating an example of functional configurations of a camera head and a CCU.

### DESCRIPTION OF EMBODIMENTS

### Configuration of Imaging Device

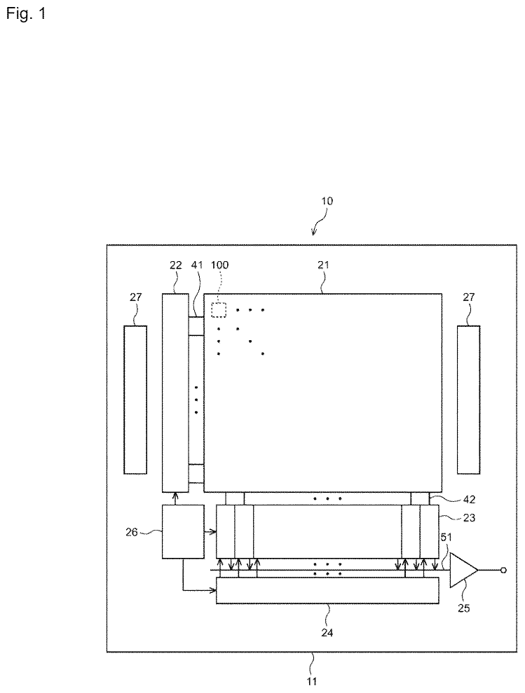

FIG. 1 is a diagram illustrating a configuration example of an imaging device to which the present disclosure is applied.

In FIG. 1, the imaging device 10 is configured as a complementary metal oxide semiconductor (CMOS) imaging device.

As illustrated in FIG. 1, the imaging device 10 includes a pixel array unit 21 in which a plurality of pixels 100 each having a photoelectric conversion region are arranged two-dimensionally in a semiconductor substrate 11 such as a silicon substrate, and peripheral circuits.

Each pixel 100 includes, for example, a photodiode (PD) serving as a photoelectric conversion region and a plurality of pixel transistors. The plurality of pixel transistors can be constituted of three transistors including a transfer transistor, a reset transistor, and an amplifier transistor. In addition to these transistors, the plurality of pixel transistors may be constituted of four transistors including a selection transistor. An equivalent circuit of the pixel 100 is commonly given, and thus, the detailed description thereof will be omitted.

The pixels 100 may have a shared pixel structure. This shared pixel structure is configured of a plurality of photodiodes, a plurality of transfer transistors, one floating diffusion (FD) to be shared, and other different types of pixel transistors to be shared. The other pixel transistors include a reset transistor, an amplifier transistor, and a selection transistor.

The peripheral circuits include a vertical drive circuit 22, column signal processing circuits 23, a horizontal drive circuit 24, an output circuit 25, a control circuit 26, and the like.

The control circuit 26 receives input clocks and data for commanding an operation mode and the like, and outputs data such as internal information of the imaging device 10. Specifically, in response to a vertical synchronizing signal, a horizontal synchronizing signal, and a master clock signal, the control circuit 26 generates clock signals to be used as a reference for and control signals for operations of the vertical drive circuit 22, the column signal processing circuits 23, the horizontal drive circuit 24, and others. These signals are then input for example to the vertical drive circuit 22, the column signal processing circuits 23, the horizontal drive circuit 24, and others.

The vertical drive circuit 22 includes, for example, a shift register, to select a pixel drive line 41 and supply a pulse for driving pixels 100 to the selected pixel drive line 41, thereby driving the pixels in units of rows. Specifically, the vertical drive circuit 22 sequentially selects and scans the respective pixels 100 in the pixel array unit 21 in the vertical direction for each row and supplies pixel signals based on signal charges generated corresponding to an amount of light received in the photoelectric conversion region of each pixel 100 to the column signal processing circuits 23 through vertical signal lines 42.

The column signal processing circuits 23 are arranged for the respective columns of pixels 100, for example, and perform signal processing such as noise removal on signals output from one row of pixels 100 for the respective pixel columns. Specifically, each column signal processing circuit 23 performs signal processing such as correlated double sampling (CDS) for removing fixed pattern noise specific to the pixel 100, signal amplification, analog-to-digital conversion (AD conversion), and the like. Horizontal selection switches (not illustrated) are connected and disposed between an output stage of the column signal processing circuits 23 and a horizontal signal line 51.

The horizontal drive circuit 24 includes, for example, a shift register, to sequentially select the column signal processing circuits 23 by sequentially outputting horizontal scan pulses, and output a pixel signal from each of the column signal processing circuits 23 to the horizontal signal line 51.

The output circuit 25 performs signal processing on signals sequentially supplied from the column signal processing circuits 23 through the horizontal signal line 51 and outputs the processed signals. For example, only buffering may be performed in some cases, and black level adjustment, column variation compensation, and various kinds of digital signal processing may be performed in other cases. Input/output terminals 27 exchange signals with the outside.

Next, an example of a structure of the imaging device 10 including the pixels 100 arranged two-dimensionally in the pixel array unit 21 will be described. In the following description, a structure will be described in which a pixel region, which is a region in which the plurality of pixels 100 are arranged two-dimensionally, is divided into four divided regions, each of which includes pixels 100.

### Structure of Upper Right Area

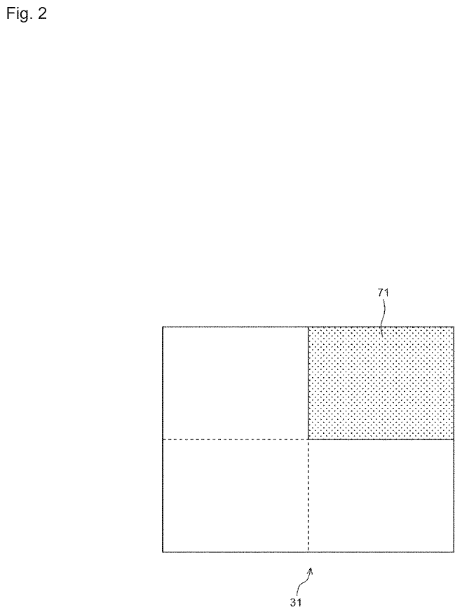

First, as illustrated in FIG. 2, the structure of an upper right area 71 that is an upper right divided region corresponding to the first quadrant of a pixel region 31 as divided into four will be described.

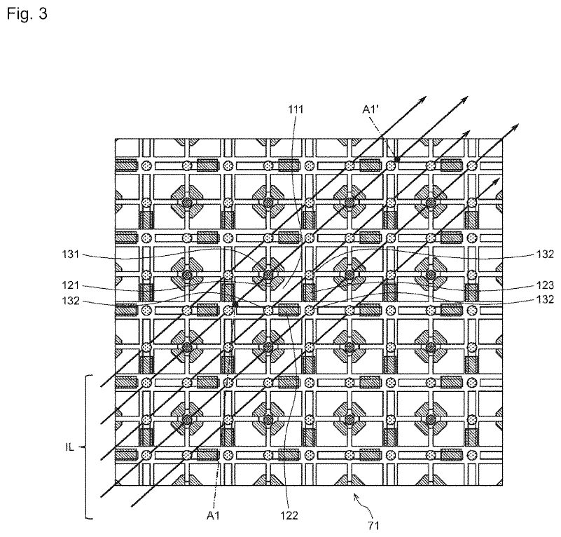

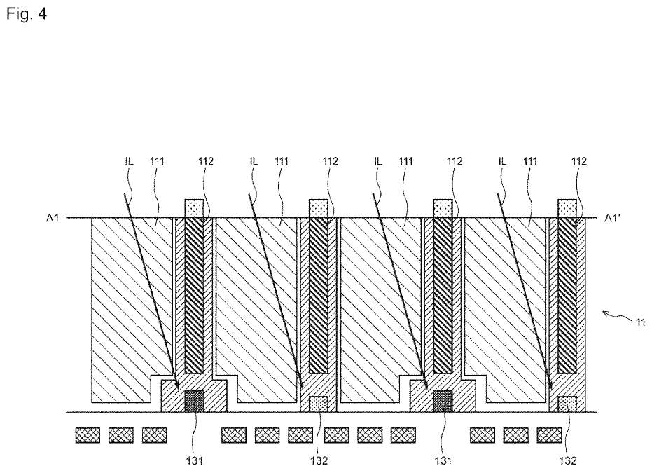

FIG. 3 is a plan view illustrating an example of a planar layout of the upper right area 71. FIG. 4 is a cross-sectional view illustrating a A1-A1′ cross section in the planar layout of FIG. 3. The planar layout of FIG. 3 corresponds to a partial region of the upper right area 71.

In FIG. 3, the plurality of pixels 100 arranged in the pixel region 31 are configured to have a shared pixel structure. This shared pixel structure includes a plurality of photoelectric conversion regions 111, a plurality of transfer transistors 121, a diffusion region 131 serving as one floating diffusion (FD) to be shared, and pixel transistors 122 and 123 to be shared. In FIG. 3, the gates of the pixel transistors 122 and 123 are represented by hatched squares. A rectangular region below each gate represents a diffusion region (diffusion layer).

A diffusion region 132 represents a diffusion region (e.g., a diffusion region of a source, a drain, etc.) included in each of the pixel transistors 122 and 123. The pixel transistors 122 and 123 are pixel transistors not including a transfer transistor, and can each be, for example, a reset transistor, an amplifier transistor, or a selection transistor.

In FIG. 3, an arrow pointing from the lower left to the upper right represents incident light IL, which is incident at a predetermined incident angle. In FIG. 3, the diffusion regions 131, each serving as a floating diffusion, and the diffusion regions 132 included in the pixel transistors 122 and 123 are formed according to the incident angle of the incident light IL that is incident on the upper right area 71 of the pixel region 31.

Here, the pixel transistors 122 and 123 are displaced to positions according to the incident angle and image height of the incident light IL so that the diffusion regions 132 are formed at positions according to the incident angle of the incident light IL. This makes a structure in which the diffusion regions 131 and the diffusion regions 132 are formed according to the incident angle of the incident light IL, and the diffusion regions (diffusion layers) are each formed in the vicinity of the photoelectric conversion region 111 at a position according to the incident light IL.

In this way, by adjusting the positions at which the pixel transistors are arranged according to the incident angle and image height of the incident light so that the diffusion regions (diffusion layers) can be formed according to the incident angle of the incident light, the influences of the pixel transistors on obliquely incident light can be equalized, making it possible to equalize the amount of color mixing from each pixel into other pixels.

For example, in a conventional configuration in which the positions of pixel transistors are not adjusted (e.g., a configuration in which the pixel transistors are arranged only in the row direction), when obliquely incident light is incident on the diffusion regions of the pixel transistors, charges are discharged therefrom, but when obliquely incident light is not incident on the pixel transistors, it is incident on other pixels due to, for example, wiring reflection, resulting in color mixing. In other words, depending on the presence or absence of pixel transistors in the incident direction of incident light, there is a possibility that the incident light will become an absorbed component that does not contribute to sensitivity, or will become a non-absorbed component that is contributes to sensitivity, for example, there is a risk that the sensitivity differences between pixels in the row direction or column direction would be affected.

In contrast, in a configuration in which the positions of pixel transistors are adjusted according to the incident angle and image height of incident light (e.g., a configuration in which the pixel transistors are arranged in the row direction and column direction) as in the present disclosure, the influences of the pixel transistors on obliquely incident light can be equalized to exhibit the same behavior. As a result, the mixed color components become equal, and thus, the influence on the sensitivity differences between pixels can be improved.

As illustrated in the cross-sectional view of FIG. 4, the pixel 100 has a photoelectric conversion region 111 formed in the semiconductor substrate 11. The pixel 100 is isolated from other pixels adjacent thereto by a pixel isolation portion 112. The pixel isolation portion 112 has an element isolation structure, such as deep trench isolation (DTI). The diffusion region 131 or the diffusion region 132 is formed under the pixel isolation portion 112. Although not illustrated, color filters and on-chip microlenses are formed on the upper surface of the semiconductor substrate 11.

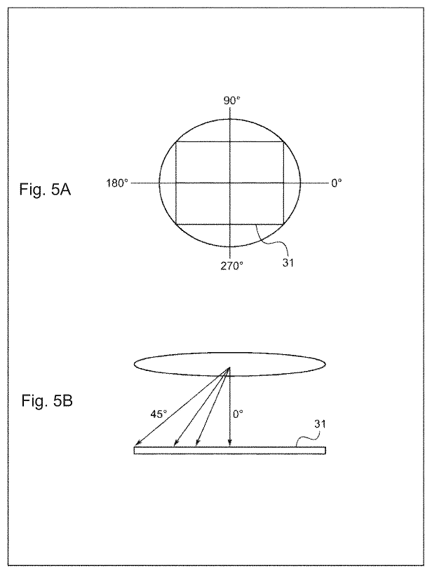

Here, the incident angle of the incident light IL that is incident on the pixel region 31, can be expressed as illustrated in A of FIG. 5. Specifically, it can be expressed as an angle with respect to the center of an arc using a circle centered on the center of the pixel region 31. For example, since the upper right area 71 corresponds to the first quadrant, the incident angle of the incident light IL is expressed as an angle in the range of 0° to 90°. In the cross-sectional view of FIG. 4, the incident angle of the incident light IL that is incident on the photoelectric conversion region 111 of each pixel 100 can be expressed as illustrated in B of FIG. 5, with the vertical direction being 0°. As used herein, unless otherwise specified, the “incident angle of incident light (light entering)” means an incident angle illustrated in A of FIG. 5.

The image height represents a distance (height) from the center of the pixel region 31. For example, in the pixel region 31, with the center being set to 0% and the corners of the region being set to 100%, the value indicating the image height increases from the center to the corners.

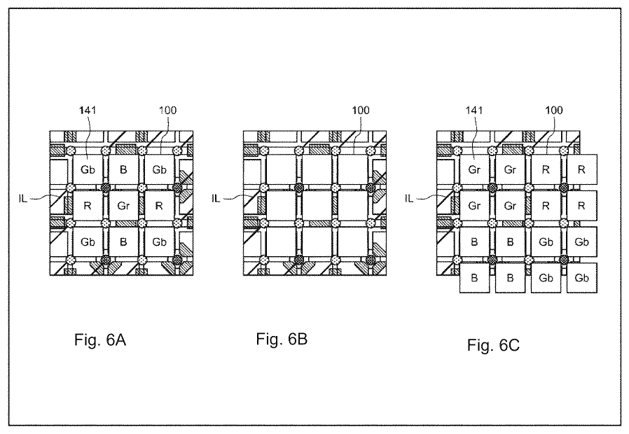

FIG. 6 is a plan view illustrating examples of a pixel array pattern in the upper right area 71.

As illustrated in A of FIG. 6, by arranging a color filter 141 that transmits wavelengths corresponding to red (R), green (G), or blue (B) for each pixel 100, R pixels, G pixels, and B pixels can be arranged regularly in a Bayer array. The Bayer array is a pixel array pattern in which G pixels are arranged in a checkered pattern, and R pixels and B pixels are arranged alternately in each row in the remaining portions. In the upper right area 71, the pixel array pattern illustrated in A of FIG. 6 can be repeatedly arranged.

As illustrated in B of FIG. 6, a structure may be adopted in which the color filter 141 is not arranged for each pixel 100, so that pixel signals for black and white can be obtained. Alternatively, as illustrated in C of FIG. 6, a pixel unit is configured using 2×2 four pixels of the same color (R pixel, G pixel, or B pixel) so that R pixel units, G pixel units, and B pixel units are arranged in a Bayer array.

The pixel array patterns illustrated in FIG. 6 are examples, and other pixel array patterns may be used, such as using a color filter corresponding to cyan (C), magenta (M), or yellow (Y).

### Structure of Upper Left Area

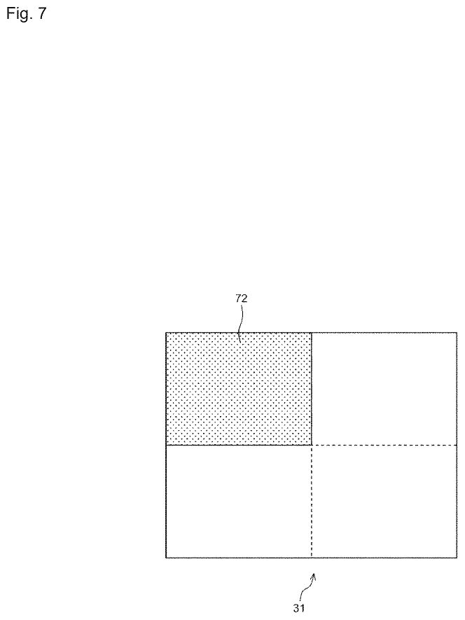

Next, as illustrated in FIG. 7, the structure of an upper left area 72 that is an upper left divided region corresponding to the second quadrant of the pixel region 31 as divided into four will be described.

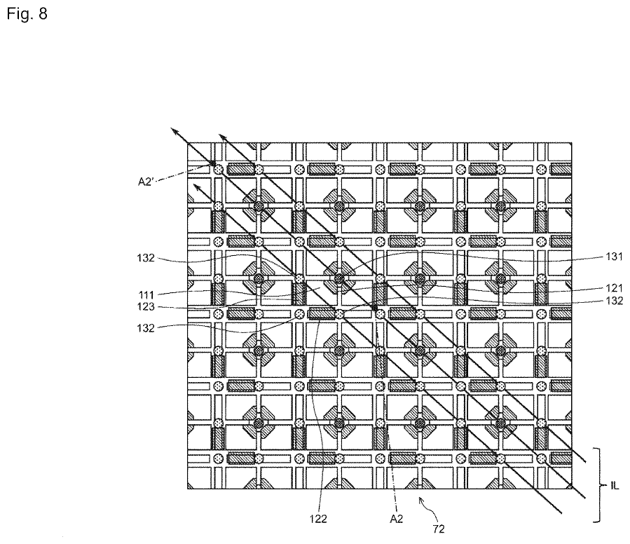

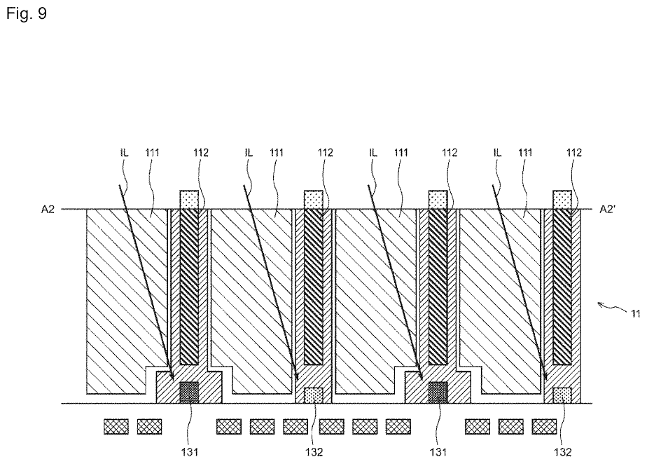

FIG. 8 is a plan view illustrating an example of a planar layout of the upper left area 72. FIG. 9 is a cross-sectional view illustrating an A2-A2′ cross section in the planar layout of FIG. 8. The planar layout of FIG. 8 corresponds to a partial region of the upper left area 72.

Similarly to the planar layout of FIG. 3, the planar layout of FIG. 8 has a shared pixel structure including a plurality of photoelectric conversion regions 111, a plurality of transfer transistors 121, a diffusion region 131 serving as one floating diffusion (FD) to be shared, and pixel transistors 122 and 123 to be shared. The diffusion region 132 is a diffusion region included in each of the pixel transistors 122 and 123 including an amplifier transistor, a selection transistor, and the like.

In FIG. 8, the diffusion regions 131, each serving as a floating diffusion, and the diffusion regions 132 included in the pixel transistors 122 and 123 are formed according to the incident angle of incident light IL indicated by an arrow pointing from the lower right to the upper left in the figure. In other words, the positions of the pixel transistors are adjusted according to the incident angle of the incident light and the image height, so that the diffusion regions are formed according to the incident angle of the incident light. As a result, even in the upper left area 72, the influences of the pixel transistors on the obliquely incident light can be equalized, making it possible to equalize the amount of color mixing from each pixel into other pixels.

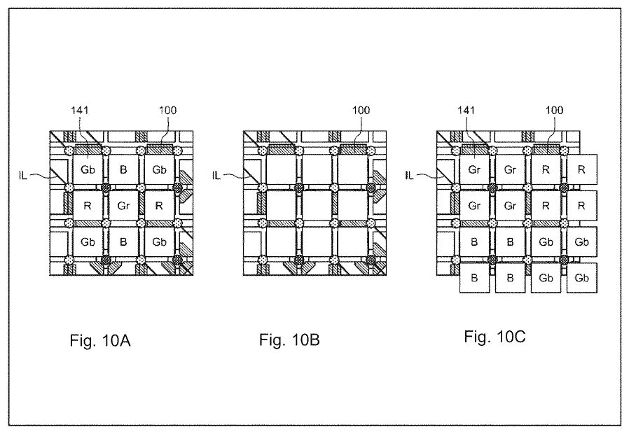

FIG. 10 is a plan view illustrating examples of a pixel array pattern in the upper left area 72.

In the upper left area 72, a pixel array pattern similar to that of the upper right area 71 illustrated in FIG. 6 can be adopted. For example, as illustrated in A of FIG. 10, by arranging a color filter 141 corresponding to a predetermined color for each pixel 100, R pixels, G pixels, and B pixels can be arranged in a Bayer array. As illustrated in B and C of FIG. 10, a structure in which the color filter 141 is not arranged, or a structure in which pixel units each including 4 pixels made up of 2×2 pixels of the same color are arranged in a predetermined array pattern may be adopted.

### Structure of Lower Left Area

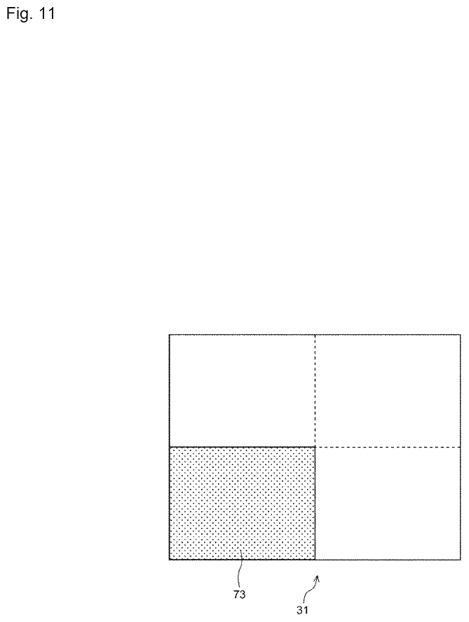

Next, as illustrated in FIG. 11, the structure of a lower left area 73 that is a lower left divided region corresponding to the third quadrant of the pixel region 31 as divided into four will be described.

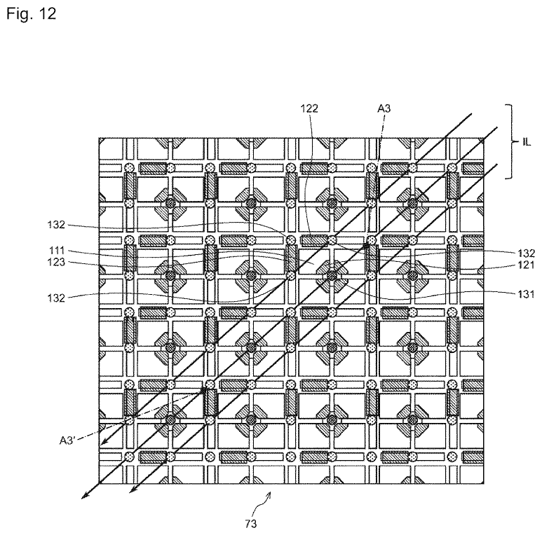

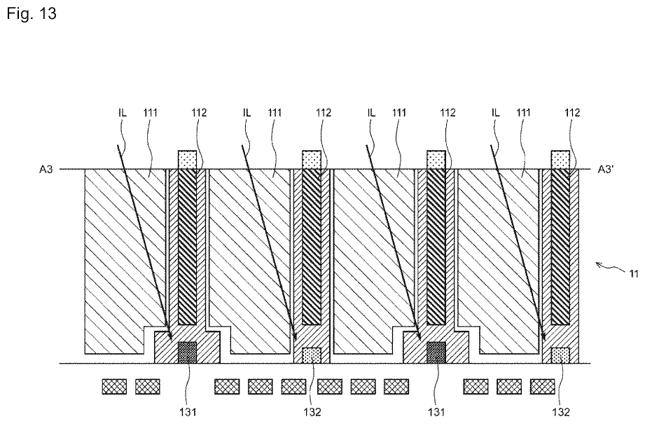

FIG. 12 is a plan view illustrating an example of a planar layout of the lower left area 73. FIG. 13 is a cross-sectional view illustrating an A3-A3′ cross section in the planar layout of FIG. 12. The planar layout of FIG. 12 corresponds to a partial region of the lower left area 73.

Similarly to the planar layout of FIG. 3, the planar layout of FIG. 12 has a shared pixel structure including a plurality of photoelectric conversion regions 111, a plurality of transfer transistors 121, a diffusion region 131 as one floating diffusion (FD) to be shared, and pixel transistors 122 and 123 to be shared. The diffusion region 132 is a diffusion region included in each of the pixel transistors 122 and 123 including an amplifier transistor, a selection transistor, and the like.

In FIG. 12, the diffusion regions 131, each serving as a floating diffusion, and the diffusion regions 132 included in the pixel transistors 122 and 123 are formed according to the incident angle of incident light IL indicated by an arrow pointing from the upper right to the lower left in the figure. In other words, the positions of the pixel transistors are adjusted according to the incident angle of the incident light and the image height, so that the diffusion regions are formed according to the incident angle of the incident light. As a result, even in the lower left area 73, the influences of the pixel transistors on the obliquely incident light can be equalized, making it possible to equalize the amount of color mixing from each pixel into other pixels.

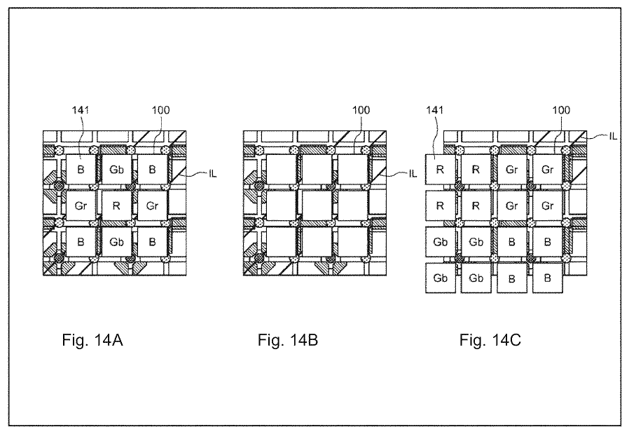

FIG. 14 is a plan view illustrating examples of a pixel array pattern in the lower left area 73.

In the lower left area 73, a pixel array pattern similar to that of the upper right area 71 illustrated in FIG. 6 can be adopted. For example, as illustrated in A of FIG. 14, by arranging a color filter 141 corresponding to a predetermined color for each pixel 100, R pixels, G pixels, and B pixels can be arranged in a Bayer array. As illustrated in B and C of FIG. 14, a structure in which the color filter 141 is not arranged, or a structure in which pixel units each including 4 pixels made up of 2×2 pixels of the same color are arranged in a predetermined array pattern may be adopted.

### Structure of Lower Right Area

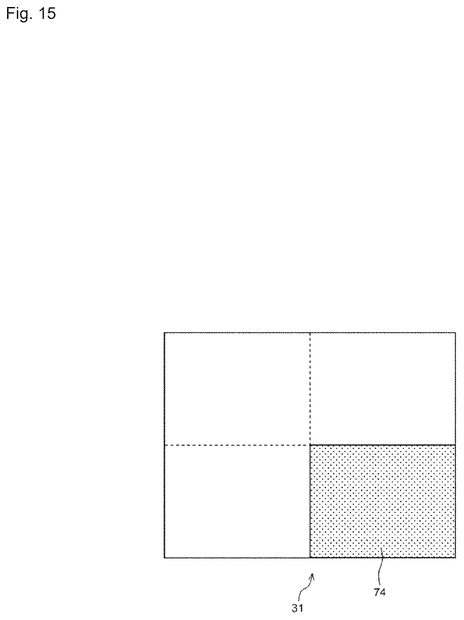

Finally, as illustrated in FIG. 15, the structure of a lower right area 74 that is a lower right divided region corresponding to the fourth quadrant of the pixel region 31 as divided into four will be described.

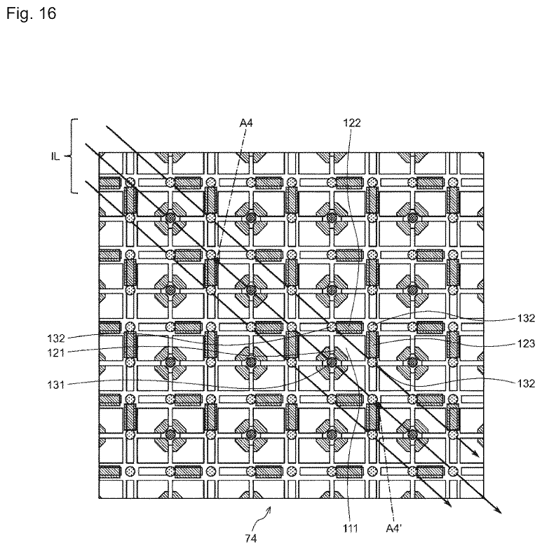

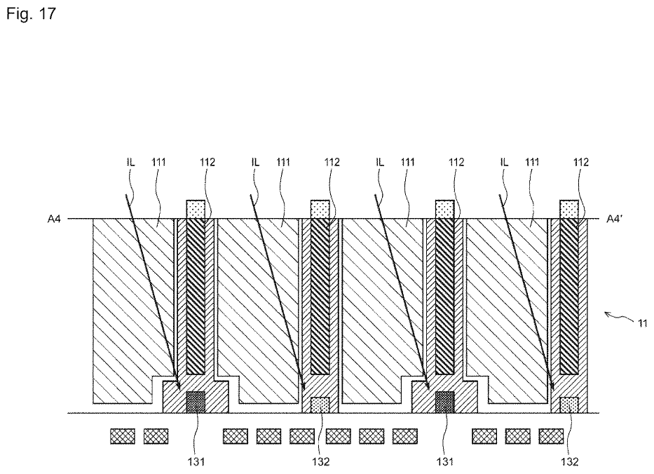

FIG. 16 is a plan view illustrating an example of a planar layout of the lower right area 74. FIG. 17 is a cross-sectional view illustrating an A4-A4′ cross section in the planar layout of FIG. 16. The planar layout of FIG. 16 corresponds to a partial region of the lower right area 74.

Similarly to the planar layout of FIG. 3, the planar layout of FIG. 16 has a shared pixel structure including a plurality of photoelectric conversion regions 111, a plurality of transfer transistors 121, a diffusion region 131 as one floating diffusion (FD) to be shared, and pixel transistors 122 and 123 to be shared. The diffusion region 132 is a diffusion region included in each of the pixel transistors 122 and 123 including an amplifier transistor, a selection transistor, and the like.

In FIG. 16, the diffusion regions 131, each serving as a floating diffusion, and the diffusion regions 132 included in the pixel transistors 122 and 123 are formed according to the incident angle of incident light IL indicated by an arrow pointing from the upper left to the lower right in the figure. In other words, the positions of the pixel transistors are adjusted according to the incident angle of the incident light and the image height, so that the diffusion regions are formed according to the incident angle of the incident light. As a result, even in the lower right area 74, the influences of the pixel transistors on the obliquely incident light can be equalized, making it possible to equalize the amount of color mixing from each pixel into other pixels.

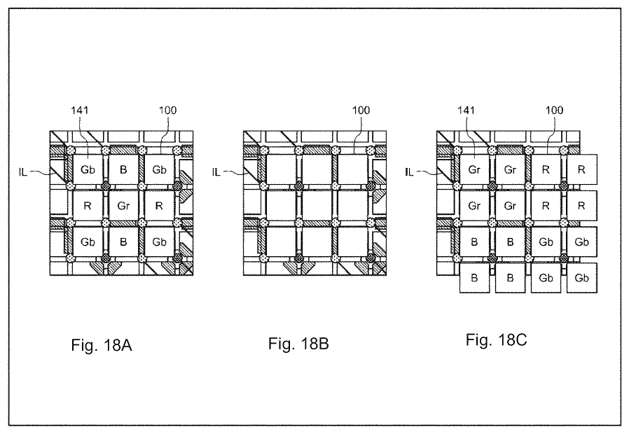

FIG. 18 is a plan view illustrating examples of a pixel array pattern in the lower right area 74.

In the lower right area 74, a pixel array pattern similar to that of the upper right area 71 illustrated in FIG. 6 can be adopted. For example, as illustrated in A of FIG. 18, by arranging a color filter 141 corresponding to a predetermined color for each pixel 100, R pixels, G pixels, and B pixels can be arranged in a Bayer array. As illustrated in B and C of FIG. 18, a structure in which the color filter 141 is not arranged, or a structure in which pixel units each including 4 pixels made up of 2×2 pixels of the same color are arranged in a predetermined array pattern may be adopted.

The structures of the upper right area 71, the upper left area 72, the lower left area 73, and the lower right area 74, which are the divided regions of the pixel region 31 as divided into four, have been described above. In each divided region, the positions of the pixel transistors are adjusted according to the incident angle of the incident light and the image height, so that the diffusion regions are formed according to the incident angle of the incident light.

For example, in the upper right area 71 illustrated in FIG. 3, now given a region of interest in which a diffusion region 131 serving as one floating diffusion to be shared, four photoelectric conversion regions 111 in the vicinity of the diffusion region 131, and four transfer transistors 121 corresponding to the four photoelectric conversion regions 111 are formed, pixel transistors 122 and 123 to be shared are adjusted to be in an array pattern such that they are arranged in a lower right corner region of the region of interest.

In the same way, pixel transistors 122 and 123 are adjusted to be in an array pattern, in the upper left area 72 illustrated in FIG. 8, such that they are arranged in a lower left corner region of the region of interest; in the lower left area 73 illustrated in FIG. 12, such that they are arranged in an upper left corner region of the region of interest; and in the lower right area 74 illustrated in FIG. 16, such that they are arranged in an upper right corner region of the region of interest. In other words, the positions of the pixel transistors are adjusted for each divided region according to the incident angle of the incident light, and the same array pattern as the region of interest in each divided region is repeatedly arranged.

In adjusting the positions of the pixel transistors in each of the four divided regions of the pixel region 31, for example, the positions of the pixel transistors the upper right area 71 illustrated in FIG. 3, the upper left area 72 illustrated in FIG. 8, the lower left area 73 illustrated in FIG. 12, and the lower right area 74 illustrated in FIG. 16 can be adjusted based on various correction amounts for each area by using a base for an optimal array pattern to determine the final positions at which they are arranged. In such an adjustment of the positions of the pixel transistors, for example, it is necessary to form contacts and wires for the gates. Accordingly, the same correction is made on the contacts and wires to ensure alignment.

In this way, by forming diffusion regions according to the incident angle of the incident light, the influences of the pixel transistors on obliquely incident light can be equalized, making it possible to equalize the amount of color mixing from each pixel into other pixels. As a result, the influence on the sensitivity differences between pixels can be improved. For example, when a Bayer array is adopted as the pixel array pattern, the influence on the sensitivity differences between Gr pixels and Gb pixels can be improved.

In addition, for the pixel transistors 122 and 123, a recessed-gate structure is used as the gate structure, an increase in the size in the W length direction can be suppressed. As a result, in adjusting the positions of the pixel transistors 122 and 123, it is possible to increase the possibility of arranging them at desired positions.

### Example of Position Adjustment of Pixel Tr According To Incident Angle

Next, an example of adjustment of pixel transistors to be arranged at positions according to the incident angle of incident light and the image height will be described. In the following description, an example of position adjustment of the pixel transistors in the upper right area 71 of the four divided regions of the pixel region 31 will be described as a representative example.

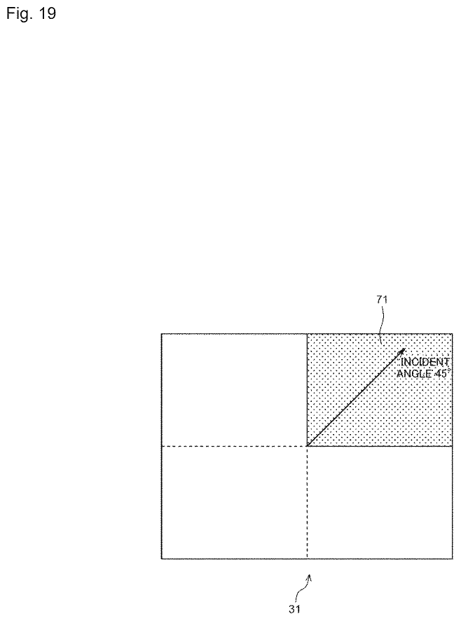

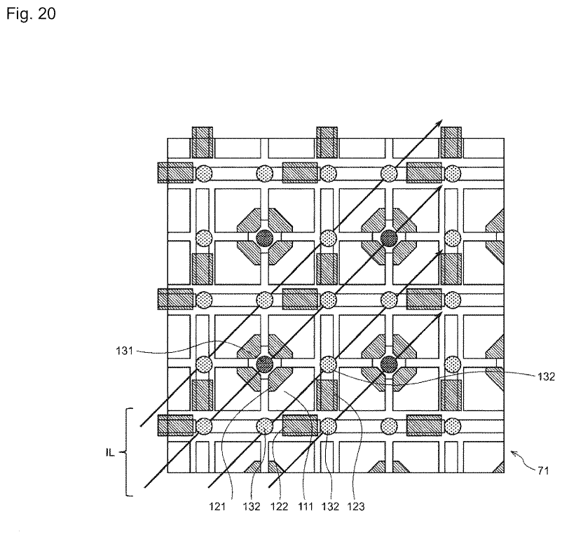

As illustrated in FIG. 19, the structure of the upper right area 71 when the incident light is incident at an incident angle of 45° can be, for example, a structure as illustrated in a planar layout of FIG. 20.

In FIG. 20, the positions of pixel transistors 122 and 123 are adjusted according to the incident angle (45°) of incident light IL and the image height. This position adjustment allows the diffusion regions 131 serving as floating diffusions and the diffusion regions 132 included in the pixel transistors 122 and 123 to be formed according to the incident angle (45°) of the incident light IL.

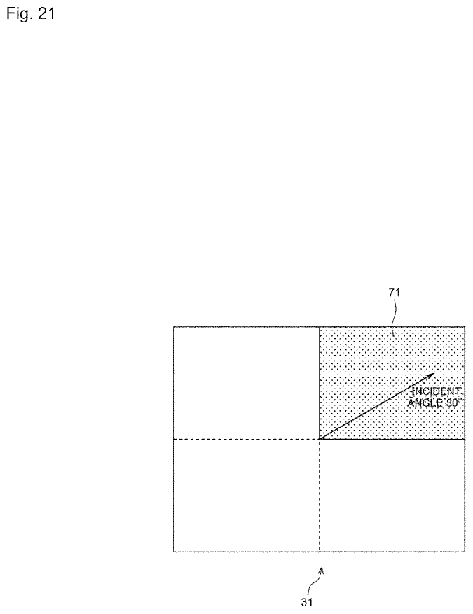

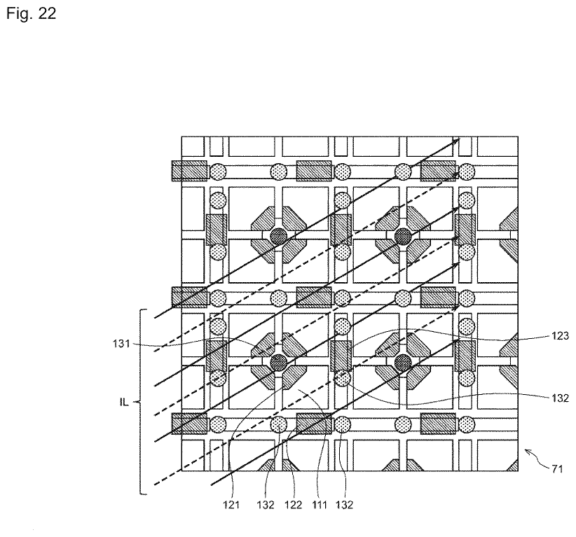

As illustrated in FIG. 21, the structure of the upper right area 71 when the incident light is incident at an incident angle of 30° can be, for example, a structure as illustrated in a planar layout of FIG. 22.

In FIG. 22, the positions of pixel transistors 122 and 123 are adjusted according to the incident angle (30°) of incident light IL and the image height. This position adjustment allows the diffusion regions 131 serving as floating diffusions and the diffusion regions 132 included in the pixel transistors 122 and 123 to be formed according to the incident angle (30°) of the incident light IL.

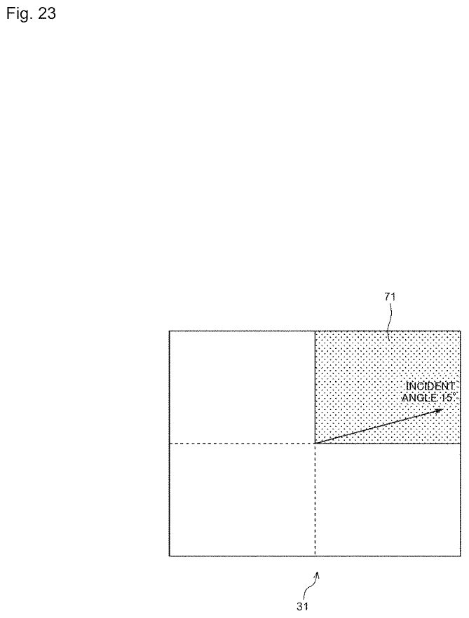

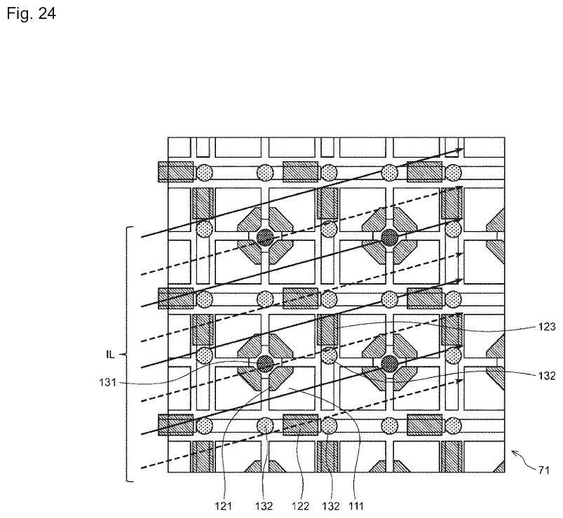

As illustrated in FIG. 23, the structure of the upper right area 71 when the incident light is incident at an incident angle of 15° can be, for example, a structure as illustrated in a planar layout of FIG. 24.

In FIG. 24, the positions of pixel transistors 122 and 123 are adjusted according to the incident angle (15°) of incident light IL and the image height. This position adjustment allows the diffusion regions 131 serving as floating diffusions and the diffusion regions 132 included in the pixel transistors 122 and 123 to be formed according to the incident angle (15°) of the incident light IL.

In this way, by adjusting the positions of the pixel transistors for each image height in the upper right area 71, they can exhibit the same behavior at any incident angle, and thus, the influences of (the diffusion regions of) the pixel transistors on obliquely incident light can be equalized. In FIGS. 19 to 24, examples of position adjustment of the pixel transistors in the upper right area 71 have been described, but in the same way, the position adjustment of the pixel transistors can be performed for other areas (divided regions). In adjusting the positions of pixel transistors, it is possible to perform the adjustment within a displaceable range in the row direction and column direction, for example, in units of regions corresponding to a plurality of pixels to be shared in a shared pixel structure.

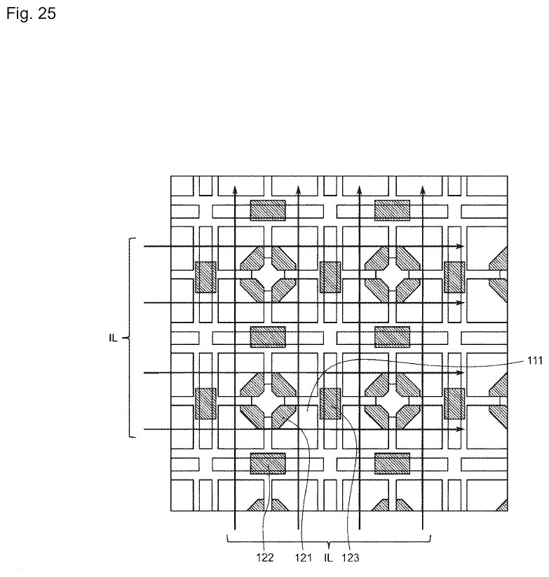

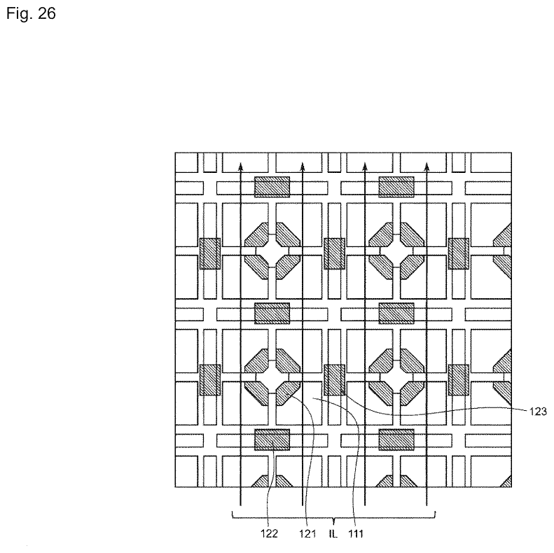

The present disclosure is applicable even to a case where the incident light is incident on the pixel region 31 in a horizontal direction (e.g., an incident angle of 0°) or a vertical direction (e.g., an incident angle of 90°), and structure examples in that case are illustrated in FIGS. 25 and 26.

In FIG. 25, the positions of the pixel transistors 122 and 123 are adjusted according to incident angles of the incident light IL in the horizontal and vertical directions (e.g., incident angles of 0° and 90°) and the image height. In FIG. 26, the positions of the pixel transistors 122 and 123 are adjusted according to the incident angle of the incident light IL in the vertical direction (e.g., an incident angle of 90°) and the image height. Even in these cases, the positions of the pixel transistors can be adjusted within a displaceable range in the row direction (horizontal direction) and column direction (vertical direction) in units of regions corresponding to a plurality of pixels to be shared in a shared pixel structure.

### Modification Example

Structures to which the present disclosure is applied have been described above by way of example in which the pixel region 31 (viewing angle) is divided into four. However, the positions of pixel transistors may be adjusted for each of the divided regions into which the pixel region 31 is divided by a number of divisions other than four, such as two or eight. Even in a case where the number of divisions is other than four, an optimal array pattern of pixel transistors may be prepared in advance for each divided region, and adjustments may be made based on various correction amounts for each divided region to determine the final positions at which the pixel transistors are arranged, as in the case of four divided regions.

Further, in the structure to which the present disclosure is applied, a shared pixel structure in which a plurality of pixels share a floating diffusion (FD) and pixel transistors is exemplified. However, the present disclosure can be applied to other structures. In particular, the present disclosure is applicable to a structure in which the sensitivity differences between pixels are affected by the positions of the pixel transistors.

The imaging device 10 is a CMOS imaging device (CMOS image sensor), and can have a back-illuminated structure in which light is incident from the upper layer (back surface side) located on the side opposite to the wiring layer side (front surface side) formed in the lower layer when viewed from the semiconductor substrate 11 in which the photoelectric conversion regions 111 are formed. The imaging device 10 may have a front-illuminated structure in which the side on which light is incident is the wiring layer side (front surface side). The structure to which the present disclosure is applied is not limited to a CMOS imaging device, but can also be applied to other imaging devices such as a charge coupled device (CCD) type of imaging device (CCD image sensor).

configuration of Electronic Apparatus

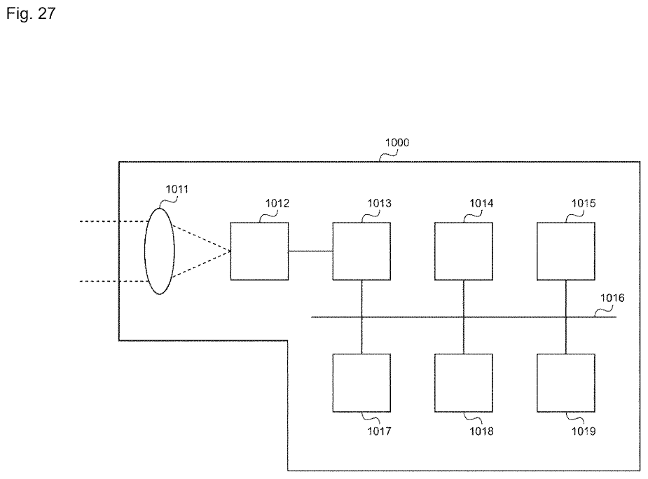

The imaging device to which the present disclosure is applied can be installed in an electronic apparatus such as a smartphone, a tablet terminal, a mobile phone, a digital still camera, and a digital video camera. FIG. 27 is a block diagram illustrating a configuration example of an electronic apparatus including the imaging device to which the present disclosure is applied.

In FIG. 27, the electronic apparatus 1000 includes an imaging system that includes: an optical system 1011 including lenses, an imaging element 1012 having functions and structure corresponding to the imaging device 10 of FIG. 1, and a digital signal processor (DSP) 1013 that is a camera signal processing unit. The electronic apparatus 1000 has a configuration in which the DSP 1013, a display 1014, an operation system 1015, a frame memory 1017, an auxiliary memory 1018, and a power supply system 1019 are interconnected to each other via a bus 1016.

The optical system 1011 captures incident light (image light) from a subject and forms an image on a light receiving surface (sensor surface) of the imaging element 1012. The imaging element 1012 converts an amount of incident light, which forms an image on the light receiving surface by the optical system 1011, into an electrical signal for each pixel and outputs the electrical signal as a pixel signal. The DSP 1013 performs various signal processing on the signal output from the imaging element 1012.

The frame memory 1017 temporarily records image data of a still image or moving image captured by the imaging system. The display 1014 is, for example, a liquid crystal display or an organic EL display, and displays the still image or moving image captured by the imaging system. The operation system 1015 receives various operations from the user and issues operation commands for various functions of the electronic apparatus 1000.

The auxiliary memory 1018 is a storage medium including a semiconductor memory such as a flash memory, and records image data of the still image or moving image captured by the imaging system. The power supply system 1019 provides each block of the electronic apparatus 1000 with various power sources serving as operating power sources as appropriate.

The configuration of the electronic apparatus 1000 illustrated in FIG. 27 is exemplary and other configurations may be used. For example, by a communication unit being provided including a communication module compatible with a predetermined communication method, the image data of the still image or moving image captured by the imaging system may be transmitted to other apparatus such as a server via a network, and receive various data from other devices.

### Application to Moving Body

The technology of the present disclosure (the present technology) can be applied to various products. For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

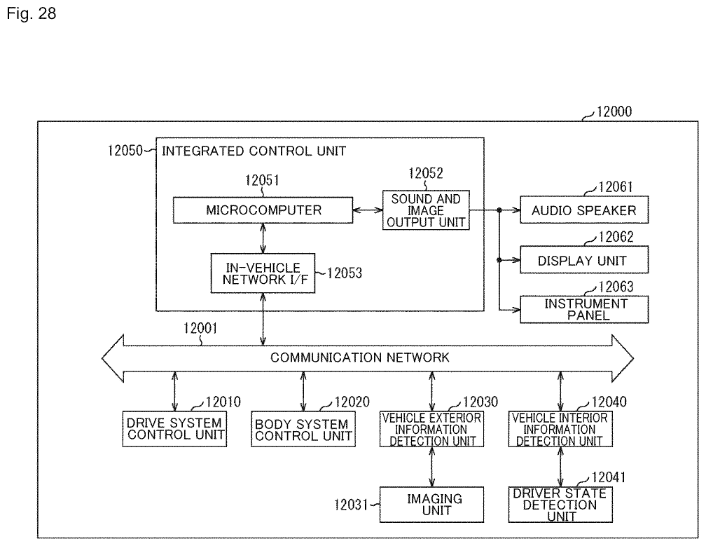

FIG. 28 is a block diagram illustrating a schematic configuration example of a vehicle control system, which is an example of a moving body control system to which the technique according to the present disclosure can be applied.

The vehicle control system 12000 includes a plurality of electronic control units connected thereto via a communication network 12001. In the example illustrated in FIG. 28, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls operations of devices related to a drive system of a vehicle in accordance with various programs. For example, the drive system control unit 12010 functions as a control device for a driving force generation device for generating the driving force of the vehicle such as an internal combustion engine or a drive motor, a driving force transmission mechanism for transmitting the driving force to the wheels, a steering mechanism for adjusting the steering angle of the vehicle, a braking device for generating the braking force of the vehicle, or the like.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for people, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

The microcomputer 12051 can also output a control command to the body system control unit 12020 based on the information outside the vehicle acquired by the vehicle exterior information detection unit 12030. For example, the microcomputer 12051 can perform cooperative control for the purpose of preventing glare such as controlling the headlamps to switch a high beam to a low beam according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example illustrated in FIG. 28, as such an output device, an audio speaker 12061, a display unit 12062 and an instrument panel 12063 are illustrated. The display unit 12062 may include, for example, at least one of an onboard display and a head-up display.

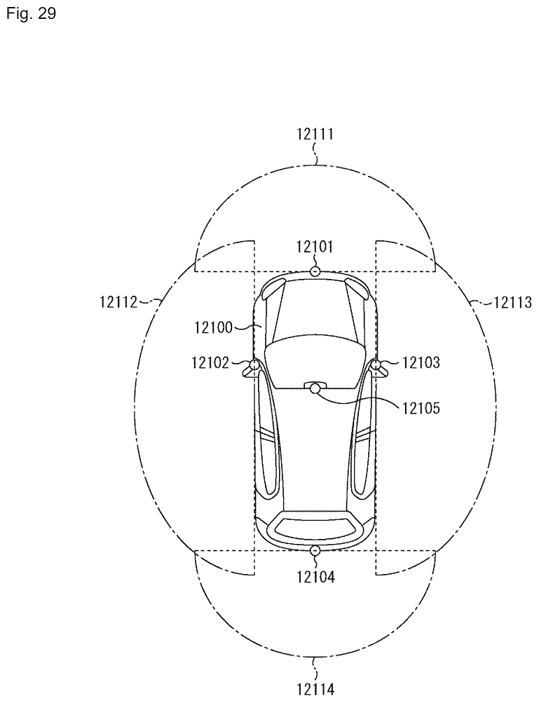

FIG. 29 is a diagram illustrating an example of installation positions of imaging units 12031.

In FIG. 29, a vehicle 12100 includes imaging units 12101, 12102, 12103, 12104, and 12105 as the imaging units 12031.

The imaging units 12101, 12102, 12103, 12104, and 12105 are provided at positions such as a front nose, side-view mirrors, a rear bumper, a back door, and an upper portion of a windshield in a vehicle interior of a vehicle 12100, for example. The imaging unit 12101 provided on the front nose and the imaging unit 12105 provided in the upper portion of the windshield in the inside-vehicle mainly acquire images in front of the vehicle 12100. The imaging units 12102 and 12103 provided on the side-view mirrors mainly acquire images of lateral sides from the vehicle 12100. The imaging unit 12104 provided on the rear bumper or the back door mainly acquires images of a side behind the vehicle 12100. The images of a front side which are acquired by the imaging units 12101 and 12105 are mainly used for detection of preceding vehicles, pedestrians, obstacles, traffic signals, traffic signs, lanes, and the like.

FIG. 29 illustrates an example of imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 viewed from above can be obtained by overlaying image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (e.g., 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into other three-dimensional objects such as a two-wheeled vehicle, an ordinary vehicle, a large-size vehicle, a pedestrian, and an electric pole on the basis of distance information obtained from the imaging units 12101 to 12104 and can use the other three-dimensional objects to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or greater than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared light. For example, the microcomputer 12051 can recognize a pedestrian by determining whether or not a pedestrian is present in captured images of the imaging units 12101 to 12104. Such pedestrian recognition is performed, for example, through a procedure of extracting feature points in the images captured by the imaging units 12101 to 12104 as infrared cameras and a procedure of performing pattern matching processing on a series of feature points indicating an outline of an object to determine whether or not the object is a pedestrian. When the microcomputer 12051 determines that pedestrians are in the images captured by the imaging units 12101 to 12104 and recognizes the pedestrians, the sound and image output unit 12052 controls the display unit 12062 such that rectangular contour lines for emphasis are superimposed and displayed on the recognized pedestrians. In addition, the sound and image output unit 12052 may control the display unit 12062 such that icons and the like indicating pedestrians are displayed at desired positions.

An example of the vehicle control system to which the technology according to the present disclosure can be applied has been described above. The technology according to the present disclosure can be applied to the imaging unit 12031 within the configuration described above. Specifically, the imaging device 10 in FIG. 1 can be applied to the imaging unit 12031. By applying the technology according to the present disclosure to the imaging unit 12031, for example, a clearer captured image can be obtained, and thus it is possible to reduce a driver's fatigue.

### Application to Endoscopic Surgery System

The technology according to the present disclosure (the present technology) can be applied to various products. For example, the technology according to the present disclosure may be applied to an endoscopic surgery system.

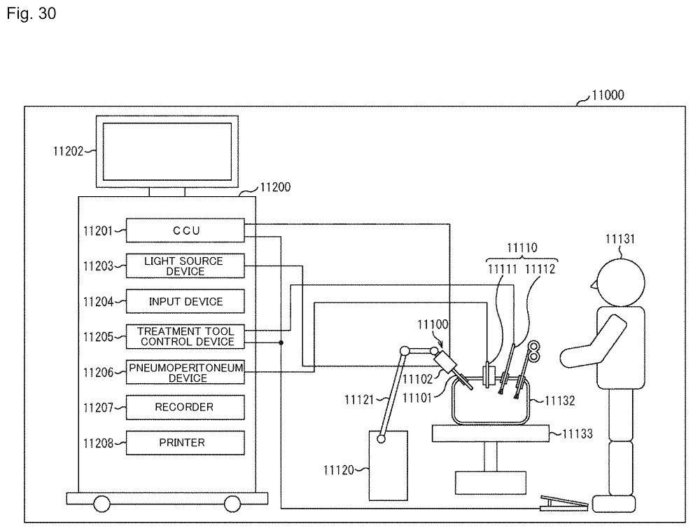

FIG. 30 is a diagram illustrating an example of a schematic configuration of an endoscope surgery system to which the technology according to the present disclosure (the present technology) is applied.

FIG. 30 illustrates a state where an operator (doctor) 11131 is performing a surgical operation on a patient 11132 on a patient bed 11133 by using the endoscopic surgery system 11000. As illustrated, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic surgery.

The endoscope 11100 includes a lens barrel 11101 of which a region with a predetermined length from a distal end is inserted into a body cavity of the patient 11132 and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light irradiates an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is constituted by a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is configured of, for example, a light source such as a light emitting diode (LED) and supplies irradiation light, which is used when a surgical part or the like is imaged, to the endoscope 11100.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls driving of the energized treatment tool 11112 for cauterization or incision of a tissue, sealing of blood vessel, or the like. A pneumoperitoneum device 11206 delivers a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the irradiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources irradiates the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter in the imaging element.

Further, driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of irradiation light (that is, white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

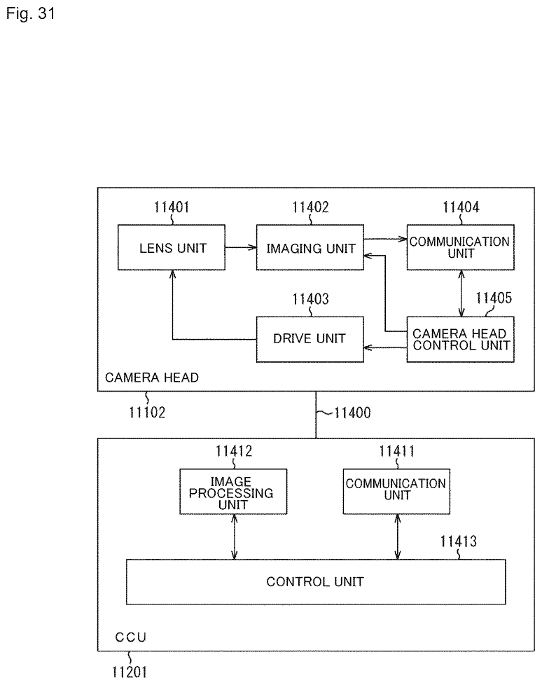

FIG. 31 is a block diagram illustrating an example of a functional configuration of the camera head 11102 and the CCU 11201 illustrated in FIG. 30.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light received from the distal end of the lens barrel 11101 is guided to the camera head 11102 and is incident on the lens unit 11401. The lens unit 11401 is configured in combination of a plurality of lenses including a zoom lens and a focus lens.

The imaging unit 11402 includes an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the operator 11131 can ascertain the depth of biological tissues in the surgical site more accurately. When the imaging unit 11402 is configured in a multi-plate type, a plurality of systems of lens units 11401 may be provided in correspondence to the imaging elements.

Further, the imaging unit 11402 does not necessarily have to be provided in the camera head 11102. For example, the imaging unit 11402 may be provided immediately behind the objective lens inside the lens barrel 11101.

The drive unit 11403 includes an actuator, and moves the zoom lens and the focus lens of the lens unit 11401 by a predetermined distance along an optical axis under the control of the camera head control unit 11405. Accordingly, the magnification and focus of the image captured by the imaging unit 11402 can be adjusted appropriately.

The communication unit 11404 includes a communication device for transmitting and receiving various types of information to and from the CCU 11201. The communication unit 11404 transmits the image signal obtained from the imaging unit 11402 as RAW data to the CCU 11201 via the transmission cable 11400.

Further, the communication unit 11404 receives a control signal for controlling driving of the camera head 11102 from the CCU 11201 and supplies the control signal to the camera head control unit 11405. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 includes a communication device for transmitting or receiving various information to or from the camera head 11102. The communication unit 11411 receives an image signal transmitted via the transmission cable 11400 from the camera head 11102.

The communication unit 11411 transmits a control signal for controlling driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various controls regarding imaging of the surgical site or the like by the endoscope 11100 and a display of a captured image obtained by imaging the surgical site or the like. For example, the control unit 11413 generates a control signal for controlling driving of the camera head 11102.

Further, the control unit 11413 causes the display device 11202 to display the captured image of the surgical site or the like on the basis of the image signal subjected to the image processing in the image processing unit 11412. In this case, the control unit 11413 may recognize various objects in the captured image using various image recognition technologies. For example, the control unit 11413 can recognize surgical instruments such as forceps, specific living parts, bleeding, mist when the energized treatment tool 11112 is used and the like by detecting the edge shape and color of the object included in the captured image. When the control unit 11413 causes the display device 11202 to display the captured image, the control unit 11413 may cause various types of surgery assistance information to be superimposed on the image of the surgical site and displayed using a result of the recognition. Superimposing and displaying the surgery assistance information and presenting the surgery assistance information to the surgeon 11131 makes it possible to reduce a burden on the surgeon 11131 and for the surgeon 11131 to reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of the endoscopic surgery system to which the technique according to the present disclosure can be applied has been described above. The technology according to the present disclosure may be applied to the imaging unit 11402 of the camera head 11102 among the configurations described above. Specifically, the imaging device 10 of FIG. 1 can be applied to the imaging unit 11402. By applying the technology according to the present disclosure to the imaging unit 11402, for example, a clearer image of the surgical site can be obtained, and thus it is possible for the surgeon to reliably check the surgical site.

Here, although the endoscopic surgery system has been described as an example, the technology according to the present disclosure may be applied to other, for example, a microscopic surgery system.

Embodiments of the present disclosure are not limited to those described above, and various changes can be made without departing from the spirit and scope of the present disclosure. For example, any structure in the embodiments described above may be combined with any other structure.

The advantageous effects described herein are merely exemplary and are not limited, and other advantageous effects may be obtained.

The present disclosure can be configured as follows.

(1)

An imaging device including a semiconductor substrate in which a plurality of pixels are formed, each pixel having a photoelectric conversion region,

wherein diffusion regions are formed in the semiconductor substrate according to an incident angle at which light is incident on a pixel region in which the pixels are arranged two-dimensionally.

(2)

The imaging device according to (1), wherein pixel transistors are arranged at positions according to the incident angle and an image height.

(3)

The imaging device according to (2), wherein the diffusion regions include diffusion regions included in the pixel transistors.

(4)

The imaging device according to any one of (1) to (3), wherein the diffusion regions include floating diffusions.

(5)

The imaging device according to (4), wherein each of divided regions into which the pixel region is divided has a different array pattern of the pixel transistors.

(6)

The imaging device according to (5), wherein

the pixel region is divided into four divided regions, and

each of the four divided regions has a different array pattern of the pixel transistors.

(7)

The imaging device according to any one of (1) to (6), including a shared pixel structure in which a plurality of pixels share one floating diffusion and the pixel transistors.

(8)

The imaging device according to (7), wherein a transfer transistor is formed for each photoelectric conversion region included in the pixel.

(9)

The imaging device according to (8), wherein the pixel transistors include a reset transistor, an amplifier transistor, and a selection transistor.

(10)

An electric apparatus including an imaging device that includes a semiconductor substrate in which a plurality of pixels are formed, each pixel having a photoelectric conversion region,

wherein diffusion regions are formed in the semiconductor substrate according to an incident angle at which light is incident on a pixel region in which the pixels are arranged two-dimensionally.

### REFERENCE SIGNS LIST

10 Imaging device
11 Semiconductor substrate
21 Pixel array unit
22 Vertical drive circuit
23 Column signal processing circuit
24 Horizontal drive circuit
25 Output circuit
26 Control circuit
27 Input/output terminal
31 Pixel region
100 Pixel
111 Photoelectric conversion region
121 Transfer transistor
122 Pixel transistor
123 Pixel transistor
131 Diffusion region
132 Diffusion region
141 Color filter
1000 Electronic apparatus
1012 Imaging element

1. An imaging device comprising a semiconductor substrate in which a plurality of pixels are formed, each pixel having a photoelectric conversion region, wherein diffusion regions are formed in the semiconductor substrate according to an incident angle at which light is incident on a pixel region in which the pixels are arranged two-dimensionally.

2. The imaging device according to claim 1, wherein pixel transistors are arranged at positions according to the incident angle and an image height.

3. The imaging device according to claim 2, wherein the diffusion regions include diffusion regions included in the pixel transistors.

4. The imaging device according to claim 3, wherein the diffusion regions include floating diffusions.

5. The imaging device according to claim 4, wherein each of divided regions into which the pixel region is divided has a different array pattern of the pixel transistors.

6. The imaging device according to claim 5, wherein the pixel region is divided into four divided regions, and each of the four divided regions has a different array pattern of the pixel transistors.

7. The imaging device according to claim 4, comprising a shared pixel structure in which a plurality of pixels share one floating diffusion and the pixel transistors.

8. The imaging device according to claim 7, wherein a transfer transistor is formed for each photoelectric conversion region included in the pixel.

9. The imaging device according to claim 8, wherein the pixel transistors include a reset transistor, an amplifier transistor, and a selection transistor.

10. An electric apparatus comprising an imaging device that includes a semiconductor substrate in which a plurality of pixels are formed, each pixel having a photoelectric conversion region,
wherein diffusion regions are formed in the semiconductor substrate according to an incident angle at which light is incident on a pixel region in which the pixels are arranged two-dimensionally.
